(19) United States
(12) Patent Application Publication
(10) Pub. No.: US 2011/0303990 A1
(43) Pub. Date: Dec. 15, 2011

(54) Semiconductor Device and Method Making Same

(75) Inventors: Erwan Dornel, Crolles Cedex (FR); Denis Rideau, Grenoble (FR); Mary Weybridgt, Grenoble (FR)

(73) Assignees: ST Microelectronics, Grenoble (FR); International Business Machines Corporation, Armonk, NY (US)

(21) Appl. No.: 13/089,529

(22) Filed: Apr. 19, 2011

(30) Foreign Application Priority Data
Jun. 9, 2010 (FR) 10305614.9

(51) Int. Cl. H01L 29/78; H01L 21/336

(52) U.S. Cl. 257/402; 438/289; 257/E21.409; 257/E29.255

(57) ABSTRACT

A FET comprising an LDD region having a high overlap extension beneath the gate thereof and a pit region on the surface of the substrate immediately below the gate and entirely surrounded by said LDD region. The surface dopant concentration is in the vicinity of the gate corner so as to reduce the local field strength, and thereby decrease the GIDL, whilst keeping high overlap extension so a to maintain a high Ion current. More particularly a region under the gate corner but enclosed by the conventional LDD is counterdoped. Counter-doping of the LDD is performed with a sufficiently low energy, a specific dose and a low angle that the counter-doped region is enclosed into the LDD (at the substrate/gate-oxide interface and keeping high overlap extension between the gate oxide and the non-counter-doped LDD). As an optimum, the counter-doped region is under the gate corner. In that way, high Ion current is ensure with a overlap length is not altered.

### FIELD OF THE INVENTION

The present invention relates to semiconductor devices, and in particular field effect transistors, and the configuration of field effect transistors so as to optimise performance, in particular as regards Gate Induced Drain Leakage.

### BACKGROUND OF THE INVENTION

Gate Induced Drain Leakage (GIDL) is a cause of the decrease of the performance of High Voltage Metal Oxide Semiconductors (HVMOS), due at least in part to the fact that the high drain voltage compared to the gate voltage creates a high electric field at the substrate/gate-oxide interface of the Field Effect Transistor (FET), as discussed in the article IEICE trans. Electron. Vol. E88-C, no 5, May 2005. by F. Gilibert, D. Rideau, A. Dray, F. Agut, M. Minondo, A. Juge, P. Masson, R. Bouchakour.

Lightly Doped Drain (LDD) engineering enables a decrease in GIDL while increasing HVMOS performance through counter-doping techniques. There are two typical counter-doping methods and aims.

FIG. 1 shows a first counter-doping technique as known in the prior art. As shown in FIG. 1 there is provided a FET 110 on a substrate 120. The FET 110 comprises a gate 111, a spacer 112 and a gate oxide layer 113. A channel 121 is formed in the substrate below the gate 111, and for the purposes of this example is assumed to be doped with p type material. As shown the SD (source/drain) region 123 for the purposes of this example is assumed to be doped with n+ type material. There is provided in accordance with this technique a Lightly Doped Drain region 122, which for the purposes of this example is assumed to be doped with n type material, which overlaps the SD region 123 and further extends beneath the gate 111, and is in contact with the gate oxide for the whole of the distance through which it extends below the gate 111. Finally there is provided in accordance with this technique a pocket region 124, which for the purposes of this example is assumed to be doped with p+ type material. This pocket region 124 envelopes the part of the LDD region 122 extending below the gate 111, and conforms substantially with the contours thereof.

FIG. 2 shows a variant of the first counter-doping technique shown in FIG. 1. FIG. 2 shows a FET 210 on a substrate 120 with a gate 111, a spacer 112 and a gate oxide layer 113. A channel 121 is formed in the substrate below the gate 111, and for the purposes of this example is assumed to be doped with p type material. As shown the SD (source/drain) region 123 for the purposes of this example is assumed to be doped with n+ type material. There is provided in accordance with this technique a Lightly Doped Drain region 122, which for the purposes of this example is assumed to be doped with n type material, which overlaps the SD region 123 and further extends beneath the gate 111, and is in contact with the gate oxide for the whole of the distance through which it extends below the gate 111. Finally there is provided in accordance with this technique a pocket region 224, which for the purposes of this example is assumed to be doped with p+ type material. This pocket region 224 forms a “bulge” extending from the corner of the LDD region 122. The pocket region is not in contact with the gate oxide layer 113.

The effect of the pocket regions 124, 224 is to prevent the punch through in the body of the FET, resulting in the creation of a parasitic BJT (Bipolar Junction Transistor) in the volume of the body, and creating Drain Induced Barrier Lowering (DIBL), whereby the threshold voltage of the FET is reduced at high voltages.

This approach does not address the issue of GIDL.

FIG. 3 shows a second counter-doping technique as known in the prior art. FIG. 3 shows a FET 310 on a substrate 120 with a gate 111, a spacer 112 and a gate oxide layer 113. A channel 121 is formed in the substrate below the gate 111, and for the purposes of this example is assumed to be doped with p type material. As shown the SD (source/drain) region 123 for the purposes of this example is assumed to be doped with n+ type material. There is provided in accordance with this technique a Lightly Doped Drain region 122, which for the purposes of this example is assumed to be doped with n type material, which overlaps the SD region 123 and further extends beneath the gate 111, and is in contact with the gate oxide for the whole of the distance through which it extends below the gate 111. Finally there is provided in accordance with this technique a counter-doped region 324, which for the purposes of this example is assumed to be doped with n-type material. This counter-doped region 324 extends sideways from the edge of the LDD region 122 further beneath the gate 111, and while generally following the lower curving edge of the LDD region, does not extend below the lower edge of the LDD region.

FIG. 4 shows a variant of the counter-doping technique described with respect to FIG. 3 as known in the prior art. FIG. 4 shows a FET 410 on a substrate 120 with a gate 111, a spacer 112 and a gate oxide layer 113. A channel 121 is formed in the substrate below the gate 111, and for the purposes of this example is assumed to be doped with p type material. The SD (source/drain) region 123 for the purposes of this example is assumed to be doped with n+ type material. There is provided in accordance with this technique a Lightly Doped Drain region 122, which for the purposes of this example is assumed to be doped with n type material, that overlaps the SD region 123 and further extends beneath the gate 111, and is in contact with the gate oxide for the whole of the distance through which it extends below the gate 111. Finally there is provided in accordance with this technique a counter-doped region 424, which for the purposes of this example is assumed to be doped with n-type material. This counter-doped region 424 intercedes between the upper limit of the LDD region and the lower edge of the spacer 112 gate oxide layer 113, and extends beneath the gate 111 slightly further than the LDD region.

The counter doped configurations described with respect to FIGS. 3 and 4 create a smoother LDD/Channel junction at the substrate/gate-oxide surface so as to decrease the junction leakage and achieve higher HVMOS performance.

Approaches corresponding or similar to those described above with respect to FIGS. 1 to 4 are presented in U.S. Pat. No. 5,308,780, U.S. Pat. No. 5,565,700, U.S. Pat. No. 4,746,624, U.S. 2006/0220120 A1, U.S. Pat. No. 6,180,470 B1 and U.S. Pat. No. 5,698,461.

### SUMMARY OF THE INVENTION

According to a first aspect of the present invention, there is provided a method of forming a semiconductor device according to the appended independent claim 1 and a semiconductor device according to the appended independent claim 7. Preferred embodiments are defined in the dependent claims.

Further advantages of the present invention will become clear to the skilled person upon examination of the drawings and detailed description. It is intended that any additional advantages be incorporating therein.

### BRIEF DESCRIPTION OF THE DRAWINGS

Embodiments of the present invention will now be described by way of example with reference to the accompanying drawings in which like references denote similar elements, and in which:

FIG. 1 shows a first counter-doping technique as known in the prior art;

FIG. 2 shows a variant of the first counter-doping technique shown in FIG. 1;

FIG. 3 shows a second counter-doping technique as known in the prior art;

FIG. 4 shows a variant of the counter-doping technique described with respect to FIG. 3 as known in the prior art;

FIG. 5 shows a first embodiment;

FIG. 6 compares the electric field levels that may be expected in a FET according to an embodiment with a conventional LDD FET;

FIG. 7 compares the drain current levels that may be expected in a FET according to an embodiment with a conventional LDD FET;

FIG. 8 shows the steps of a conventional process for forming an LDD FET;

FIG. 9 shows a method of forming a FET in accordance with embodiments of the present invention; and

FIG. 10 shows a method of forming a FET in accordance with embodiments of the present invention.

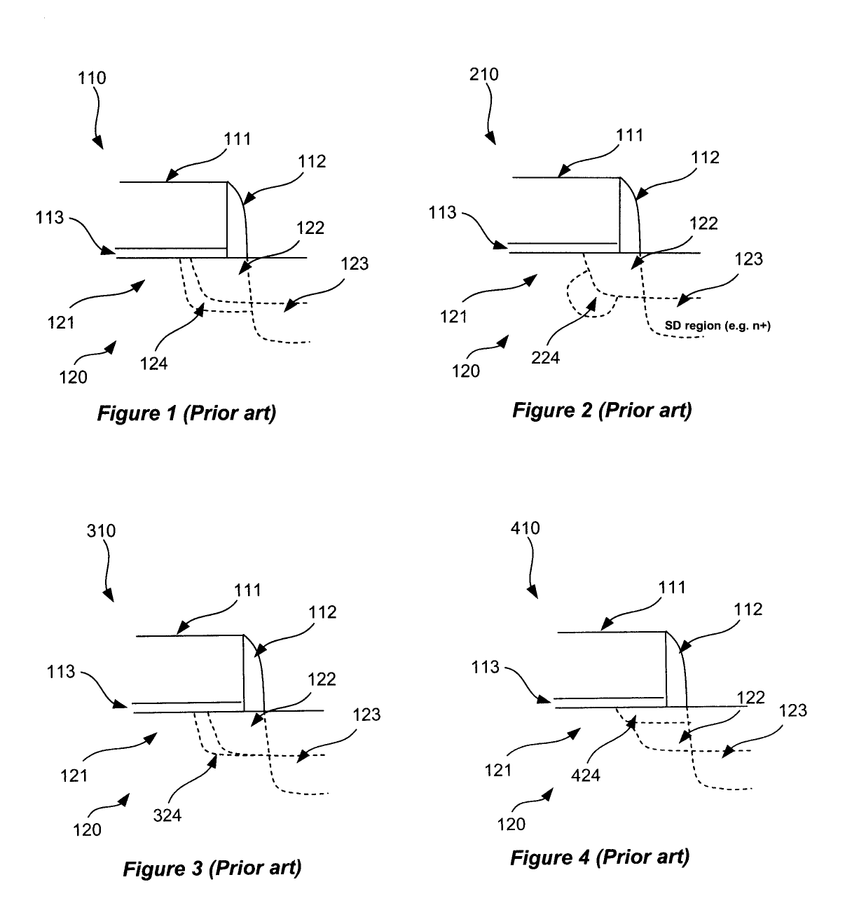

### DETAILED DESCRIPTION OF THE PREFERRED EMBODIMENT

LDD implant conditions are usually fixed to ensure a trade-off between low current leakage and high Ion current. In addition to channel off-current, gate oxide leakage and junction leakage, the leakage current can be generated near the drain/substrate junction and for high drain-to-gate voltages. This leakage current, called the GIDL, is especially high for the HVMOS devices. The root cause of the GIDL may be band-to-band tunneling currents or trap-assisted-tunneling currents as discussed in the article IEEE, Int. Conference on Microelectronics Test Structures, Vol. 17, March 2004 by D. Rideau et al. The GIDL is generally located on the surface of the substrate immediately below the gate corner. Moreover, the GIDL is very localized. The present invention proposed a method to decrease the GIDL by only modifying the area where the GIDL is created. Hence, the present invention allows decreasing the GIDL current without altering the Ion current.

It is proposed to change the surface dopant concentration in the vicinity of the gate corner so as to reduce the local field strength, and thereby decrease the GIDL, whilst keeping high overlap extension to maintain a high Ion current. More particularly it is proposed to counter-dope into a region under the gate corner but enclosed by the conventional LDD.

Accordingly, a counter-doped LDD is performed, (i.e. with a reverse dopant type than the conventional LDD), with a sufficiently low energy, a specific dose and a low angle that the counter-doped region is enclosed into the LDD (at the substrate/gate-oxide interface and keeping high overlap extension between the gate oxide and the non-counter-doped LDD). Optimally, the counter-doped region is under the gate corner. In that way, high Ion current ensures the overlap length is not altered.

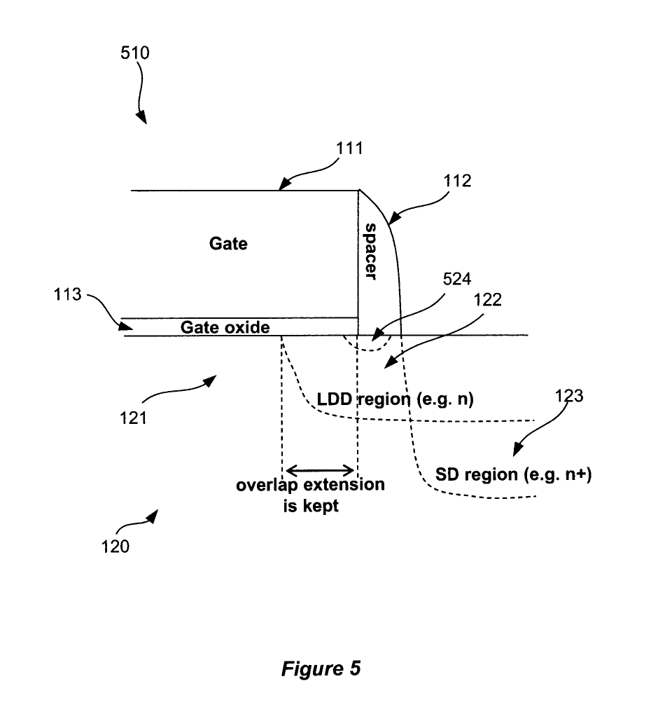

FIG. 5 shows a first embodiment of a FET 510 on a substrate 120 with a gate 111, a spacer 112 and a gate oxide layer 113. A channel 121 is formed in the substrate below the gate 111, and for the purposes of this example is assumed to be doped with p type material. As shown the SD (source/drain) region 123 for the purposes of this example is assumed to be doped with n+ type material. There is provided in accordance with this technique a Lightly Doped Drain region 122, which for the purposes of this example is assumed to be doped with n type material, that overlaps the SD region 123 and further extends beneath the gate 111, and is in contact with the gate oxide for the whole of the distance through which it extends below the gate 111.

In accordance with this embodiment, a pit region 524 is provided, which for the purposes of this example is assumed to be doped with p type material, that is, the reverse dopant type to the nearby conventional LDD. Pit region 524 is formed on the surface of the substrate 120 immediately below and preferably abutting the interface between the spacer 112 and gate oxide layer 113, and is entirely surrounded by the LDD region 122, which extends a significant distance beneath the gate 111. The pit region is preferably formed immediately below the drain side edge of said gate. LDD overlap length may range from a few nanometers (recently developed technologies) to few hundreds of nanometers. Accordingly, the pit region length may range from a few nanometers to a few tens of nanometers with an optimum at 10% of the LDD overlap length.

Accordingly there is provided a method of forming a semiconductor device such as a FET comprising the steps of defining a LDD region by implanting dopants associated with a first charge carrier polarity, in this case n type material associated with negatively charge carriers, with a low angle so as maintain a high overlap extension beneath the gate of the FET, and forming a pit region on the surface of the substrate immediately below the gate of the FET and entirely surrounded by the LDD region by implanting dopants associated with a second charge carrier polarity.

To form such a pit region 524, a low energy counter-doping is recommended to change the surface doping concentration to a suitably shallow depth, and low angle counter-doping is preferable to maintain a high overlap extension in the LDD region.

There is accordingly defined a semiconductor device with an LDD region having a high overlap extension beneath the gate thereof and a pit region on the surface of the substrate immediately below the gate and entirely surrounded by said LDD region.

In operation, the counter-doped pit region has the effect of decreasing the electric field generated by a high drain voltage (referred to gate voltage) located in this specific region which can be a root cause of GIDL. But the overlap length kept high enables the device to maintain a high ion density.

For an NMOS FET, the LDD implant may be any dopant known to a person of skill in the art, typically a group V element such as phosphorus, arsenic or antimony. The counter-doping in the pit region will then typically be a group IIIA element such as boron, indium or aluminium, or a molecular dopant such as BF₂

For a PMOS FET, the LDD implant may be any dopant known to s person of skill in the art, typically a group IIIA element such as boron or aluminium. The Counter-doping in the pit region will then typically be a group V element such as phosphorus, arsenic or antimony.

The FET may also comprise a CMOS device, including PMOS and NMOS transistors, and wherein the counter-dopant is a group V element for the PMOS transistors and a group III element for the NMOS.

The counter-dopant is preferably implanted with an energy of less than 40 keV. The counter-dopant is more preferably implanted with an energy between 0.2 keV and 20 keV.

In a case where the counter-dopant includes Boron, the Boron counter-dopants are preferably implanted with an energy of less than 7 keV.

In a case where the counter-dopant includes Arsenic, the Arsenic counter-dopants are preferably implanted with an energy of less than 30 keV.

In a case where the counter-dopant includes Boron, the Boron counter-dopants are preferably implanted with an energy of less than 7 keV.

The counter-dopant is preferably implanted with a dose between 5e10 cm−2 and 5e14 cm−2. The counter-dopant is still more preferably implanted with a dose between 5e11 cm−2 and 5e13 cm−2. The counter-dopant is still more preferably implanted with a dose between 1e13 cm−2 and 2.5e13 cm−2.

The counter-dopant is preferably implanted with a angle of between 0° and 30°, and more preferably with a angle between 0° and 15° and still more preferably with a angle between 0° and 5°.

By way of example, a structure as described above with respect to FIG. 5 may be implemented in an NMOS technology using the following variables:
LDD implant(s): Phosphorus, 28 keV, 4^{e}13 cm⁻², 30°
Counter-doped LDD implant(s): Boron, 2 keV, 1^{e}13 cm ⁻², no implantation angle
Spacer formation: Spacers are helpful so the source/drain implants do not overlap the LDD which would create a steep PN junction. Spacers are commonly used in current technologies.
HDD implants: Phosphorus, 20 keV, 6e13 cm−2, and Arsenic 20 keV, 1e15 cm−2, and Phosphorus 6 keV, 2e15 cm−2 HDD implants are necessary to highly dope the source/drain regions in order to get a low resistivity.

The counter-doped implant may be performed before or after the gate FET patterning.

The LDD and the counter-doping LDD may be implanted only on one side of the gate of the FET, or both. Preferably, the counter-doping LDD is implanted in the drain side only.

The non-counter-doped LDD implant may be performed before or after the counter-doped LDD implant. Further, the counter-doping LDD may be implanted in several steps where a different dopant type belonging to the same element group or to element group IV, with a possible different dose, energy and angle is implanted at each step.

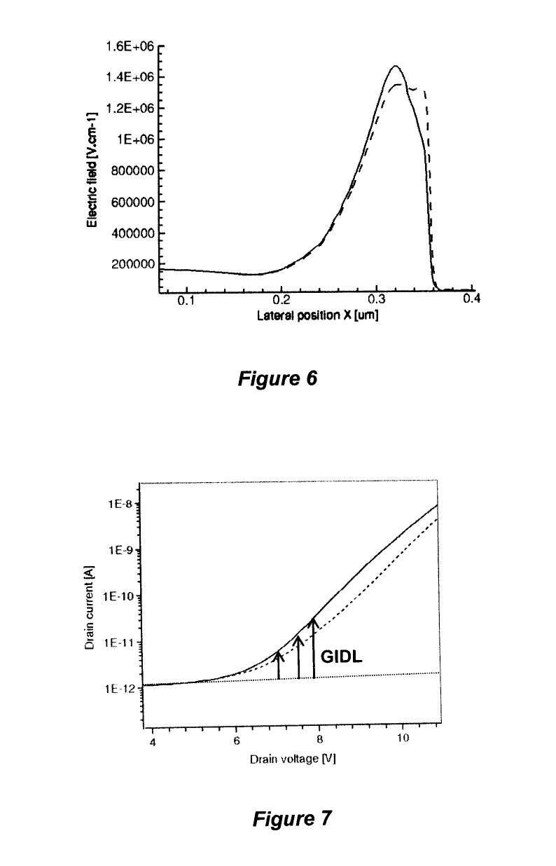

FIG. 6 compares the electric field levels that may be expected in a FET according to an embodiment with a conventional LDD FET. More particularly, FIG. 6 shows the electric field level that may be expected at the interface between the gate and the substrate as a function of the distance along the channel, based on a TCAD simulation of the exemplary implementation described above. The solid line represents the electric field levels that may be expected in a conventional LDD FET, whilst the broken line represents the electric field levels that may be expected in a FET according to an embodiment as described above. As can be seen, while in both transistors the field strength rises to a maximum in the vicinity of the drain side edge of the gate, in the case of the conventional transistor the electric field rises to a peak around 1.5×10⁶ V/cm, whilst the transistor according to an embodiment as described above plateaus at 1.4×10⁶ V/cm. This is considered to be the result of the counter-doped pit region 524 at the substrate/gate oxide interface as described above.

FIG. 7 compares the drain current levels that may be expected in a FET according to an embodiment with a conventional LDD FET. More particularly, FIG. 7 shows the drain current level that may be expected at drain voltage levels, with null gate, source and substrate voltages, based on a TCAD simulation of the exemplary implementation described above. The solid line represents the drain current levels that may be expected in a conventional LDD FET, whilst the broken line represents the drain current levels that may be expected in a FET according to an embodiment as described above. As can be seen, while in both transistors from around 6V, a GIDL drain current component is visible which rises somewhat proportionally to Drain voltage, this GIDL component grows more quickly for the conventional transistor so that the GIDL component for the conventional transistor is consistently higher for all drain voltage values at which GIDL is apparent. The disparity is greatest around 8.4 volts, where the GIDL of the transistor according to an embodiment as described above is around 75% of that of the conventional transistor.

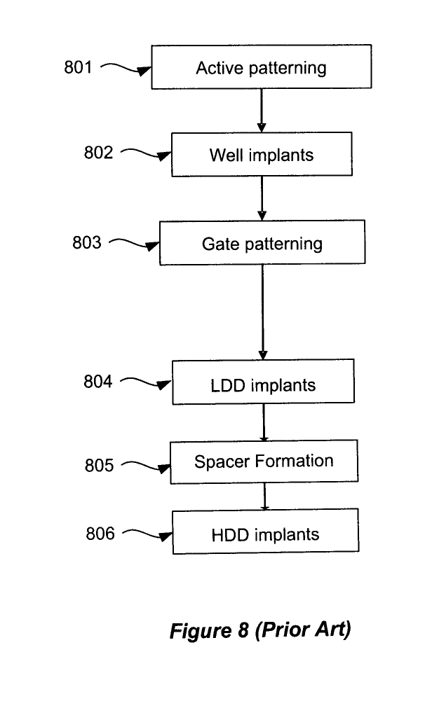

FIG. 8 shows the steps of a conventional process for forming an LDD FET. As shown in FIG. 8, the method starts at step 801 at which the active areas of the semiconductor surface are defined by selectively oxidizing the interceding areas. The method then proceeds to step 802 at which dopants appropriate to the technology type and functional role are implanted in certain of the active regions defined at step 801 to form well regions as required, i.e. in the case of CMOS technology. The method then proceeds to step 803 at which point the gates of the devices are formed in the appropriate locations on each device. The method then proceeds to step 804 at which point further dopants are implanted so as to form the Lightly doped drain area the gates of the devices are formed in the appropriate locations on each device. The LDD dopants will again be selected according to the desired properties of the device and the technology in which it is implemented. In the case of the example described above, the LDD implant will be of n type material. At step 805, the spacers 112 are formed. The method then proceeds to step 806 in which dopants appropriate to the technology type and functional role are implanted in the active regions defined at step 801 to form Highly Doped Drain regions. For example to form an N channel FET as described above, N+ material may be implanted in the SD regions.

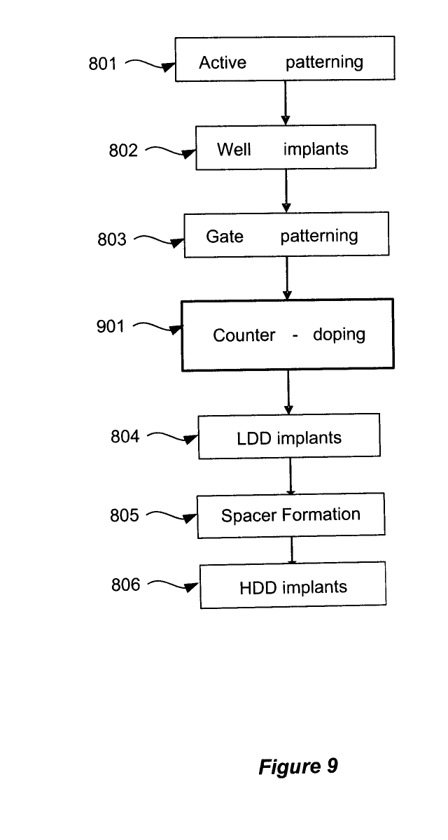

FIG. 9 shows a method of forming a FET in accordance with embodiments of the present invention. FIG. 9 depicts similar steps as described with regard to FIG. 8. There is provided a further step 901 of counter-doping, between the steps 803 of gate patterning and 804 of LDD implantation as described above. Step 901 includes counter-doping part of an active region at a low energy, a specific dose and a low angle that the counter-doped region is enclosed within the LDD region (although the LDD doping has yet to occur), at what will become the substrate/gate-oxide interface to form the counter-doped pit region 524 as described above with respect to FIG. 5. Step 804 is then carried out with a low angle implantation counter-doping to maintain a high overlap extension in the LDD region and a high overlap extension between the gate oxide and the LDD region.

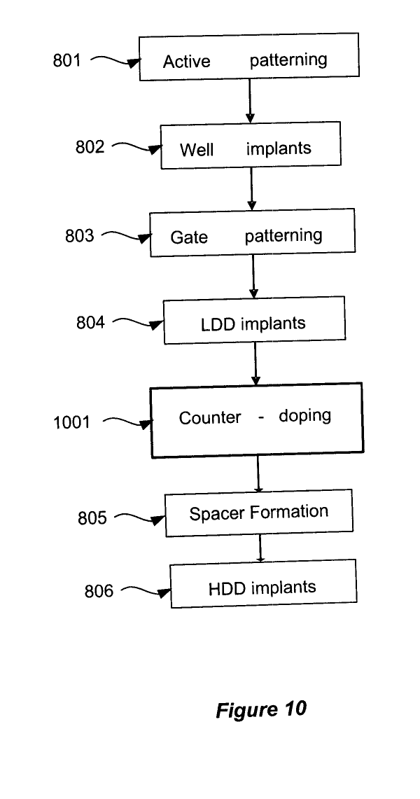

FIG. 10 shows a method of forming a FET in accordance with embodiments of the present invention. FIG. 10 depicts similar steps as described in FIG. 8. There is provided a further step 1001 of counter-doping, between the steps 804 of LDD implantation as described above and step 806 of providing HDD implants. Step 804 is then carried out with a low angle so as to maintain a high overlap extension between the gate oxide and the LDD region, and Step 1001 then comprises counter-doping part of the LDD with a sufficiently low energy, a specific dose and a low angle that the counter-doped region is enclosed into the LDD (at the substrate/gate-oxide interface and keeping high overlap extension between the gate oxide and the non-counter-doped LDD), so as to form the counter-doped pit region 524 as described above with respect to FIG. 5.

According to certain embodiments, steps 901 and 1001 may be carried out as a series of separate counter-doping events, or may be preceded by an additional amorphisation step. For example, the counter-doping implanted at step 901 or 1001 may be implanted in several steps with different dopant types belonging to the same element group or to element group IV, with a possible different dose, with a different energy and/or a different angle. By this means the crystal structure at the surface of the pit region 534 is amorphised, such that dopants implanted in the same region in successive implantation steps tend to penetrate less deeply, leading to a shallower pit region.

The skilled person will appreciate that while certain steps have been described in a particular order, these steps may be re-ordered in various ways without loosing the benefits ascribed to the present invention. For example, while the step of counter-doping to form the pit region may be carried out either before or after the definition of the LDD region, it may also be carried out before or after said step 803 of gate patterning. Certain steps such as the step 805 of forming the spacer may be omitted altogether.

The FET may constitute any type of FET device, and is particularly suited to MOSFET/IGFET/MISFET type devices, and more particularly to planar FET structures including drift MOS (DMOS) or extended drain MOS (EDMOS) devices.

While embodiments have been described with reference to FET devices, the skilled person will appreciate that the above teaching is applicable to any electronic device with high electric field issue at a “re-entering corner”.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A method of forming a semiconductor device comprising the steps of:
providing a gate electrode over a substrate,
defining a lightly doped drain (LDD) region having an overlap extension beneath said gate by implanting dopants associated with a first charge carrier polarity, and
forming a pit region on the surface of the substrate immediately below the gate of said semiconductor device and entirely surrounded by said LDD region by implanting dopants associated with a second charge carrier polarity with a low angle of implantation so as not to alter the overlap extension beneath the gate of said semiconductor device.

2. The method of claim 1, wherein said pit region is formed immediately below the drain side edge of said gate.

3. The method of claim 2, wherein said step of defining a pit region by implanting said dopants associated with a second charge carrier polarity comprises implanting said dopants associated with a second charge carrier polarity with an angle ranging from 0° to 30°.

4. The method of claim 3, wherein said step of forming a pit region comprises implanting dopants associated with a second charge carrier polarity with a dose between 1e13 cm−2 and 2.5e13 cm−2.

5. The method of claim 4, wherein said step of forming a pit region comprises implanting dopants associated with a second charge carrier polarity with a low energy.

6. The method of claim 5, wherein said step of forming a pit region comprises implanting BF2 with an energy of less than 40 keV.

7. The method of claim 6, wherein said step of forming a pit region comprises implanting dopants associated with Boron with an energy of less than 7 keV.

8. The method of claim 7, wherein said step of forming a pit region comprises implanting Arsenic with an energy of less than 30 keV.

9. A semiconductor device comprising a gate isolated regarding a substrate and a lightly doped drain (LDD) region having a high overlap extension beneath the gate thereof and a pit region on the surface of the substrate immediately below the gate and entirely surrounded by said LDD region, the LDD region and the pit region having a different doping type.
